(19) United States
(12) Patent Application Publication
(10) Pub. No.: US 2004/0080917 A1
(43) Pub. Date: Apr. 29, 2004

(54) Integrated microwave package and the process for making the same

(76) Inventors: Clark Morrison Steddom, Fallbrook, CA (US); Joseph Santo Occhipinti, Carlsbad, CA (US); Michael Frank Roffey, Oceanside, CA (US); Juan Luis Sepulveda, Tucson, AZ (US); Jeffrey Allyn Karker, Cazenovia, NY (US)

Correspondence Address: CALFEE HALTER & GRISWOLD, LLP, 800 SUPERIOR AVENUE, SUITE 1400, CLEVELAND, OH, 44114, US

(21) Appl. No.: 10/278,424

(22) Filed: Oct. 23, 2002

(51) Int. Cl. H05K 7/02

(52) U.S. Cl. 361/748

(57) ABSTRACT

The present invention provides for a integrated microwave package that has a non-conductive base having a conductive layer disposed on a first surface thereof and a shielding wall and lid which are grounded to a ground plane that is disposed on a second surface of the non-conductive base. The integrated microwave package for RF, microwave, and millimeter wave signals, as applied to the field of microelectronic and optoelectronic applications, eliminates the need for an external metallic housing and reduces the EMI noise propagation. The integrated microwave package provides a high level of functionality and can be used in high power and high frequency applications that exhibit low insertion loss across a very wide pass band.

### FIELD OF THE INVENTION

The present invention relates to a package for housing electronic components and a process for making the same.

### BACKGROUND

Various conventional integrated microwave packages that house microelectronics are often constructed with circuitry mounted on a non-conductive base which is contained in a metal enclosure, also known as a metal housing. The metal housing which typically includes a metal substrate, and metal sidewalls and a metal lid attached to the metal substrate, can provide rigidity to the non-conductive base and circuitry. The metal housing can also function as a heat sink to enhance the transfer of heat out of the integrated microwave package. Although the metal housing provides these benefits, provisions must be made to assemble the housing and to mount the non-conductive base and circuitry to the housing. This results in added cost to provide and to use these microwave packages.

In other conventional microwave packages the non-conductive base is mounted onto a metal substrate, however, either the walls or the lid, or both, are electrically isolated. A problem with such integrated microwave packages is that the presence of isolated lid can result in an increasing amount of electromagnetic interference (EMI) noise, with increasing power levels and frequencies. The EMI interference adversely affects the near environment outside the package which causes deleterious affects the semiconductors, circuitry, components, and devices, that are both internal and external to the package especially at high frequency and high power.

In addition, the applications which use microwave packages have become increasingly demanding in terms of functionality, the frequency and power requirements. Microwave packages require good impedance control and low insertion loss at high frequencies that can reach 100 GHz and higher. Thus, it would be desirable to increase the functionality and performance of microwave packages and to lower the manufacturing cost.

### SUMMARY

The present invention provides for an integrated microwave package used for amplification, signal processing, or transmission or reception of electrical signals, preferably conventional RF signals, and suitable for high frequency applications of up to about 100 GHz, and in some applications exceeding 100 GHz. The integrated microwave package as used herein is meant to include packages suitable for conventional RF, microwave and millimeter wave applications. The package includes a non-conductive base onto which microelectronic, optoelectronic and digital components can be mounted. A grounded shielding wall and grounded lid are mounted onto the non-conductive base to protect the microelectronic components from the external environment. The non-conductive base provides isolation from the ground at desired locations as well as mechanical strength and rigidity, thus eliminating the need for additional housing components and reducing the number of steps necessary for assembly. In addition to producing an integrated microwave package at lower cost, the present invention also provides for increased functionality. Circuit designs are enhanced by multilayer circuit structures having circuitry with integrated passives. Cavities and pedestals in the non-conductive base provide for coplanar RF designs and heat sinks.

In one embodiment of the invention the integrated microwave package includes a non-conductive base having a first surface and a second surface opposite the first surface. The first surface of the non-conductive base has a first conductive layer that includes a conductive pattern having integrated passives disposed thereon and transmission lines for transmitting RF signals, DC, and power in and out of the integrated microwave package. Transmission line signals range from direct current (DC) to conventional radio frequency (RF), and reaching up to microwave and even millimeter-wave frequency signals. The integrated microwave package can also accommodate the transmission of digital signals. A first ground layer is disposed on at least a portion of the second surface of the non-conductive base. The integrated microwave package also includes a shielding wall disposed on the first surface of the non-conductive base, and the shielding wall is grounded by electrical contact with a via that connects the first surface of the non-conductive base to the ground plane. The shielding wall defines a mounting area inside the perimeter of the shielding wall for mounting electrical components and semiconductors. The transmission line of the conductive layer extends from the mounting area and under the shielding wall to a location exterior the shielding wall. The integrated microwave package further includes a dielectric layer bonded to a portion of the transmission line that extends under the shielding wall to isolate the transmission line.

In another embodiment of the invention the integrated microwave package further includes an integrated circuit that is mounted onto the first surface of the non-conductive base and is electrically connected to the first conductive layer. In another embodiment the integrated microwave package also includes a conductive lid that is attached to the shielding wall and is electrically connected to the ground plane. The integrated circuit is connected to the conductive pattern and the transmission line to transmit RF and DC signals in and out of the integrated microwave package. In this embodiment, the non-conductive base together with the shielding wall and lid possess mechanical strength and rigidity, and provide for a integrated microwave package that is rugged while having fewer housing components than conventional packages. The grounded shielding wall and lid shield the integrated microwave package from electromagnetic interference (EMI) noise that can adversely affect the performance of the package and the semiconductor external to the package.

In any of the embodiments described above, at least a portion of the first surface of the non-conductive base further includes a first multilayer circuit structure disposed on the mounting area defined by the shielding wall. The first multilayer circuit structure can include integrated conductive patterns and passive components. In another embodiment of the invention, the first multilayer circuit structure extends underneath the shielding wall.

In another embodiment of the invention, the integrated microwave package can further include a second multilayer circuit structure disposed thereon. In one arrangement, the first ground layer is disposed between the second surface of the non-conductive base and the second multilayer circuit structure. In any of these arrangements, the shielding wall and the lid are grounded and are electrically connected to the first ground layer. In another arrangement, the second multilayer circuit structure can be disposed between the second surface of the non-conductive base and the first ground layer.

In another embodiment of the invention, the non-conductive base of the integrated microwave package has a cavity for mounting an integrated circuit. Preferably, the integrated circuit is recessed in the cavity so that it is substantially coplanar with the conductive layer and transmission line disposed on the first surface of the non-conductive base. In this arrangement, the integrated circuit is thereby substantially coplanar with the RF signal transmitted through the transmission line. A coplanar electrical connection is accomplished using interconnect bonding technology to achieve an integrated microwave package having less insertion loss.

In another embodiment of the invention, the integrated microwave package in any of the above embodiments can further comprise a pedestal for mounting the integrated circuit. The pedestal can be attached to the first surface of the non-conductive base or within a cavity in the non-conductive base, and is preferably sized such that an integrated circuit mounted on it achieves coplanarity with the RF signal. For example, the pedestal can be sized such that the integrated circuit mounted thereon is substantially coplanar with a conductive layer of the non-conductive base, the conductive layer of a multilayer circuit, a transmission line or combinations thereof. In another embodiment of the invention the pedestal is made of a material that has a greater thermal conductivity than the non-conductive base to achieve improved heat transfer from the integrated circuit to an external heat sink and better thermal expansion match to the semiconductor material used for the integrated circuit.

In any of the embodiments described above, the integrated microwave package of the invention may further include an optical fiber which allows light to be transmitted in and out of the package for optoelectronic applications. In one embodiment, the optical fiber extends through the shielding wall, the lid, or through the non-conductive base. The integrated microwave package can further include an active optical component disposed on the mounting area defined by the shielding wall and connected to the optical fiber to detect, emit or modulate light. The optical fiber may have access to the interior of the package through a metallic hossel connector attached to the shielding wall or the lid, and the package can be hermetically sealed.

Similarly, in yet other embodiments of this invention, the package further includes brazed or soldered DC or RF/microwave connectors attached to at least one of the non-conductive base, shielding wall, and lid. The connectors can include, but are not limited to, SMA, APC 3.5, K and semi-rigid-type connectors.

### BRIEF DESCRIPTION OF THE DRAWINGS

The features and advantages of the present invention will become apparent from the general description of the invention given above and the following detailed description of the invention when read with the accompanying drawings in which:

FIG. 1 is a plan view of an integrated microwave package for housing microelectronic components according to one embodiment of the present invention;

FIG. 2 is a cross-sectional view of the integrated microwave package along line 2-2 of FIG. 1 and further comprising an integrated circuit and a lid according to another embodiment of the invention;

FIG. 3 is an exploded view of the integrated microwave package of FIG. 2 according to one embodiment of the invention;

FIG. 4 is a cross-sectional view of an integrated microwave package having a pedestal according to another embodiment of the invention;

FIG. 5 is a cross-sectional view of an integrated microwave package having a pedestal according to another embodiment of the invention;

FIG. 6 is a cross-sectional view of an integrated microwave package having a multilayer circuit structure on the non-conductive base according to another embodiment of the invention;

FIG. 7 is a cross-sectional view of an integrated microwave package having a multilayer circuit structure that extends under the shielding wall according to another embodiment of the invention;

FIG. 8 is a cross-sectional view of an integrated microwave package having a transmission line that is co-planar with the multi-layer circuit according to another embodiment of the invention;

FIG. 9 is a cross-sectional view of an integrated microwave package having a ground plane across the entire surface of the non-conductive base according to another embodiment of the invention; and

FIG. 10 is a cross-sectional view of an integrated microwave package in which the non-conductive base has a cavity and an integrated circuit that is disposed in the cavity and is co-planar with the RF plane according to another embodiment of the invention.

### DETAILED DESCRIPTION

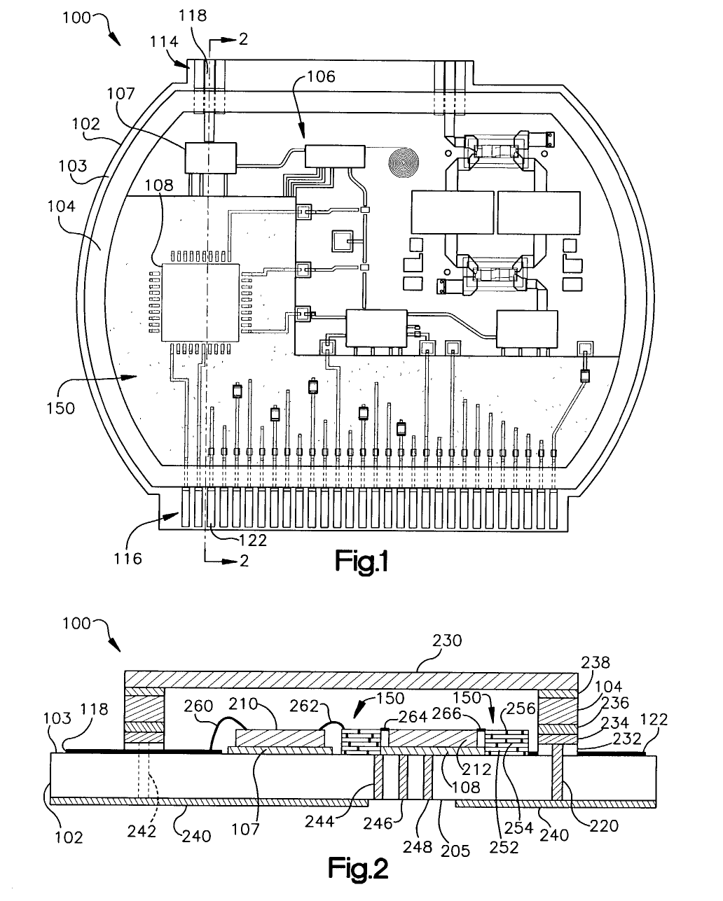

Referring to FIG. 1, according to one embodiment of the invention, is a top plan view of an integrated microwave package 100 without a lid. The integrated microwave package as used herein is meant to include microwave packages that process conventional RF, microwave or millimeter wave signals. The integrated microwave package shown in FIG. 1 includes a non-conductive base 102, a shielding wall 104, and a conductive layer 106 disposed on a first surface 103 of the non-conductive base 102. The non-conductive base can be any non-conductive material, for example, a ceramic material that includes, but is not limited to, beryllium oxide (BeO), aluminum oxide (Al₂O₃), aluminum nitride (AlN), zirconia (Zr₂O₃), fused silica (SiO₂) and titanates, such as, for example, barium titanate (BaTiO₃) and lanthanum titanate. The non-conductive base 102 is metallized in certain areas to provide at least one integrated conductive pattern and bonding pads, for example, bonding pads 107 and 108 that facilitate the attachment of integrated circuits.

The conductive layer 106 is made of a metal offering advantages in electrical and thermal conductivity and includes, but is not limited to, for example, gold, platinum-gold, platinum, silver, copper, silver-palladium, gold-platinum-palladium, silver-platinum-palladium, copper-silver, and combinations thereof. Conductive layer 106 includes a conductive pattern that can also include passive components such as resistors, capacitors, inductors, couplers, Lange couplers, coils, filters, and any other electrical integrated or discrete components. Conductive layer 106 also includes transmission lines 118 and 122 which can transmit radio frequency (RF) signal, direct current (DC) or other signals through the integrated microwave package. Conductive layer 106 can also include bonding pads 107 and 108 for attaching integrated circuits which can be electrically connected to the conductive pattern, the transmission lines and other electrical components. Conductive layer 106 is preferably applied by thick-film, high resolution deposition technology which will be described in more detail below with regard to the process for making the integrated microwave package.

The shielding wall 104 is attached to the first surface 103 of the non-conductive base 102 and is conductive and electrically connected to a ground layer (not shown) and is discussed further below with reference FIG. 2 below. By attached it is meant that the shielding wall is secured, either directly or indirectly, to the non-conductive base. The internal perimeter of the shielding wall 104 defines a mounting area along the first surface 103 of the non-conductive base 102 and the shielding wall protects the electrical components mounted within. The shielding wall 104 can be made of metal or a non-metallic material, for example, ceramic, that is metallized. A non-metallic material can be metallized by one of a variety of methods known well by those skilled in the art, for example, by thick-film deposition which includes screen printing, for example. Metallization can also be achieved by well-known thin-film techniques such as by sputtering, or physical and chemical vapor deposition processes or evaporation.

Integrated microwave package 100 also includes lateral feedthrough structures 114 and 116 which allow for the transmission of signals between the interior package and the external environment. Feedthrough structure 114 is shown in FIG. 1 as having a transmission line 118 that is coplanar from outside the shielding wall 104 to coplanar stripline under the shielding wall to coplanar structure inside the boundary of the shielding wall 104. A coplanar transmission line is defined as dielectric substrate having a signal conductor on one surface and two ground electrodes, which run adjacent to the signal conductor, on the same surface. The coplanar stripline transmission segment under the shielding wall 104 has the signal conductor and the two ground electrodes that run adjacent to the signal conductor buried within a dielectric and sandwiched between two ground planes. In the stripline arrangement, the signal electrode is buried within a dielectric and sandwiched between two ground planes. Feedthrough structure 116 is shown in FIG. 1 as having a transmission line 122 that is microstrip outside the shielding wall to coplanar stripline under the shielding wall to microstrip inside the shielding wall. A microstrip transmission line is made of a dielectric substrate with a signal conductor on one surface and a ground plane on the opposite surface. Planar transmission structures are described in Thin Film Handbook, Elshabini-Riad and Barlow, McGraw-Hill, 1998, pp. 10-3 and 10-4. Transmission line 122 can also be a DC line that allows power input or other signals in and out of the integrated microwave package.

The cross-sectional view of package 100 along line 2-2 of FIG. 1 is shown in FIG. 2. The cross-section is taken through transmission line 118 at one end of the integrated microwave package and via 220 at an opposite end of the integrated microwave package. In this embodiment the integrated microwave package further includes integrated circuits 210 and 212 and a lid 230. The cross-section shows a first ground layer 240 that extends along at least a portion of a second surface 205 which is opposite of first surface 103 of non-conductive base 102. The first ground layer 240 can be made out of a variety of metals, such as, for example, gold, platinum-gold, platinum, silver, copper, silver-palladium, gold-platinum-palladium, silver-platinum-palladium, copper-silver, gold-silver-platinum, gold-silver-palladium, and combinations thereof. Vias 220 and 242 extend through non-conductive base 102 and thereby electrically connect the shielding wall 104 and the lid 230 to the ground layer 240.

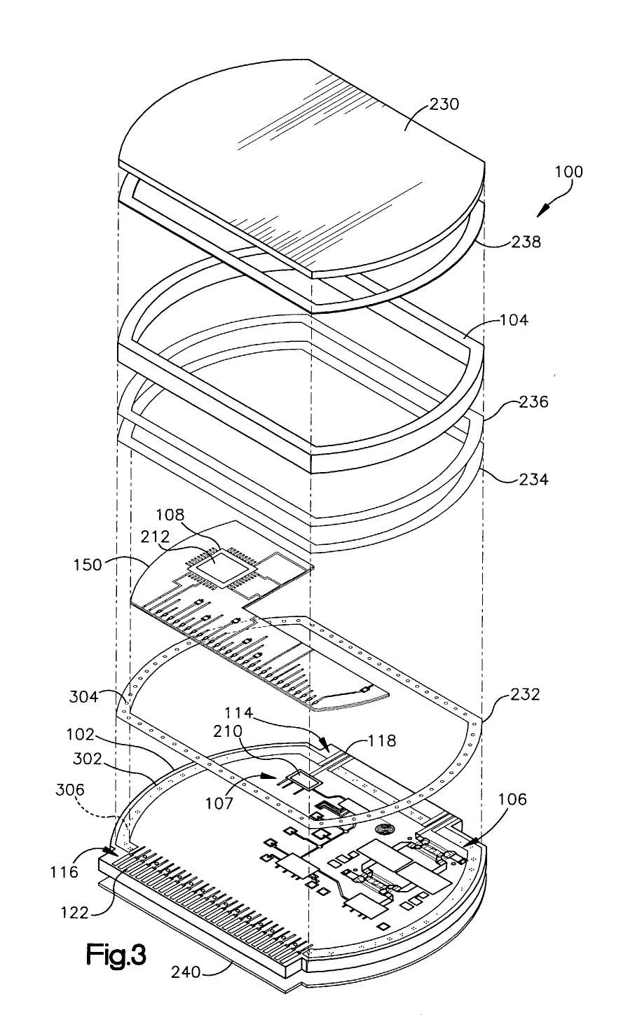

Transmission lines 118 and 122 run under the shielding wall 104 between a location on the mounting area of the non-conductive base to a location outside the shielding wall. In order to electrically isolate the transmission lines from the shielding wall, an isolating layer 232 is disposed between the transmission lines and the shielding wall 104. Isolating layer 232 can be made of any material that insulates the transmission lines from ground, such as, for example, “tape transfer” tape and dielectric paste. Although isolating layer 232 is needed only to cover and isolate the transmission lines, the dielectric layer can be sized to substantially match the shape of the shielding wall 104 as will be discussed in more detail below with respect to FIG. 3.

In another embodiment, the integrated microwave package further includes a metallization layer 234 disposed between the isolating layer 232 and the shielding wall 104 to facilitate attachment of the shielding wall. On any portion of the metallization layer 234 can be any appropriate metallization material that will adhere to the isolating layer 232, such as, for example, gold, silver, molybdenum-manganese, molybdenum-tungsten, silver-palladium, silver-palladium-platinum, gold-silver-palladium, gold-silver-platinum, titanium-tungsten or copper. In some systems, an additional layer of gold or nickel plating will be required for attachment of the shielding wall 104. When the metallization layer 234 is applied, a first bonding layer 236 bonds the metallization layer 234 to the shielding wall 104. The first bonding layer 236 can be made of any soldering or brazing compound, such as, for example, or gold-tin, gold-germanium, gold-silicon, gold-indium, tin-lead, lead-indium, copper-silver, or any other appropriate brazing alloy known to those of ordinary skill in the art. These materials are heated over their melting temperature to braze the shielding wall 104 to the metallization layer 234. Alternatively, the non-conductive base 102 and the shielding wall 104 can be joined without a metallization layer if the first bonding layer 236 is a suitable conductive adhesive or conductive epoxy that can bond a conductive and a non-conductive material.

Metallized vias provide a pathway for grounding the shielding wall 104 to the ground layer 240. Via 220 and via 242 (shown in phantom) extend from metallization layer 234, and through dielectric layer 234, and non-conductive base 102, to the ground layer 240. In addition, at least one metal via extends from the first surface to the second surface of the non-conductive base to facilitate grounding. The microwave or millimeter wave package also includes additional vias for RF and DC interconnection to devices outside the package. For example, via 244 grounds conductive layer 106 to ground layer 240. Via 246 and via 248 provide electrical connection from the bonding pad 108 to RF or DC interconnections to devices external to the electronic package.

In another embodiment of the invention, the integrated microwave package further includes an integrated circuit. FIG. 2 cross-section of electronic package 100 shows integrated circuits 210 and 212 mounted on mounting pads 107 and 108, respectively. Integrated circuit 112 is electrically connected to transmission line 118 and 122 to transmit RF or DC signal into and out of the integrated microwave package. Conductive layer 106 can also include a plurality of leads that extend from mounting pads 107 and 108 to electrically connect the integrated circuit to the conductive pattern and the transmission lines. The integrated circuits can include a ball grid array for flip chip attachment to the mounting pads or could use bumped chip attachment technology. The integrated circuit can also be attached onto the bonding pads by brazing, for example, using gold-tin, gold-germanium, or gold-silicon at a temperature of about 300-400° C. Several interconnecting bonding technologies can be used to electrically connect the integrated circuit to transmission lines and the conductive patterns to one another. These include, but are not limited to, wire bonding, ribbon bonding, gold ball bonding, thermosonic gold ball bonding, aluminum wedge/wedge bonding and gold wedge/wedge bonding.

In another embodiment of the invention the integrated microwave package further includes a lid 230 attached to the shielding wall 104. The lid is preferably made of metal or alternatively, of a non-metallic material, for example, ceramic, that is metallized in the same manner as described above with respect to the shielding wall 104. Lid 230 can be attached to shielding wall 104 by conventional attachment techniques such as seam welding, laser welding, brazing, solder sealing, and other methods of joining metal to metal. Alternatively, the lid 230 can be attached to the shielding wall 104 by a second bonding layer 238 made of any material that bonds the lid to the shielding wall and is conductive, such as, for example, a metallic brazing compound, a conductive epoxy, or other organic adhesives which are conductive. The lid 230 is thereby electrically connected to the shielding wall 104 and is grounded to the first ground layer 240. In another embodiment, the shielding wall and lid are one monolithic member that is formed by stamping or machining a conductive material. The monolithic member can be attached to the non-conductive base 102 by using the same methods described above in attaching the shielding wall to the non-conductive base, for example, by using conductive epoxy or by brazing or solder sealing. The integrated microwave package described above and having a non-conductive base, shielding wall and lid can be hermetically sealed and can meet the gross and fine leak requirements of standard MIL-STD-883 Method 1014.10 which requires a maximum leakage of 10⁻⁸ cc/sec or less of helium.

In any of the embodiments described above the integrated microwave package can further include a multilayer circuit structure disposed on at least a portion of the non-conductive base. FIGS. 1 and 2 show multilayer circuit structure 150 disposed on a portion of the first surface 103 of non-conductive base 102. A multilayer circuit structure as defined herein has at least two conductive layers separated by a dielectric layer. The first multilayer circuit structure includes at least a portion of the first conductive layer disposed on the first surface of the non-conductive base; a first dielectric layer disposed on at least a portion of the first conductive layer; and, a second conductive layer disposed on the first dielectric layer. Each dielectric layer has a conductive layer having a predetermined conductive pattern of interconnect metallization and a plurality of metalized vias extending therethrough which interconnect the adjacent conductive layers. The interconnect metallization and vias of the multilayer circuit structure extend from the first conductive layer disposed on the non-conductive base to the top surface of the multilayer circuit structure.

FIG. 2 shows multilayer circuit structure 150 which has a plurality of dielectric layers, for example, dielectric layer 252 and alternating conductive layers, for example, conductive layer 254. Conductive layer 254 has at least one conductive pattern and at least one via 256 filled with conductive material to interconnect the conductive layers between the dielectric layers. FIG. 2 shows the plurality of staggered vias, for example, via 256 between the dielectric layers. The conductive layers have conductive patterns to connect the staggered vias. Although not shown, some vias may also be stacked on top of one another through each dielectric layer. Thus, electrical and thermal interconnections are provided by the plurality of staggered and stacked vias and conductive layers. The top conductive layer of the multilayer circuit structure can include integrated passive components, for example, resistors, capacitors, and other electrical circuit elements.

Via 244, which extends from the multilayer circuit structure 150 to the second surface 105 of the non-conductive base 102, provides thermal and electrical interconnection between components on the first surface 103 and second surface 205 of non-conductive base 102. The conductive layers and filled vias can be any metal, preferably, gold, silver, copper, or combinations thereof which have excellent electrical conductivity, and preferably depending upon the location of the via, excellent thermal conductivity.

Multilayer circuit structure 150 is connected to and integral with the conductive layer 106 disposed on first surface of non-conductive base, and can be electrically connected to integrated circuits 210 and 212. In FIG. 2, integrated circuits 210 and 212 can be mounted to a first surface 103 of non-conductive base 102. Integrated circuit 210 is electrically connected to transmission line 118 by wire bond 260 and to multilayer circuit structure 150 by wire bond 262. Integrated circuit 112 is electrically connected to multilayer circuit structure 150 by ribbon bonds 264 and 266. However, any of the several interconnecting bonding technologies described above can be used to connect the multilayer circuit structure to integrated circuits and to transmission lines.

The process for making the integrated microwave package of the present invention is better explained with reference to FIG. 3 which illustrates an exploded view of the integrated microwave package 100 of FIG. 2, according to another embodiment of the present invention. The process includes forming openings or holes in the non-conductive base 102, for example, by laser drilling or punching or other forming methods which are well known by those skilled in the art. A conductive material is used to fill or coat the holes to produce vias, feedthroughs, or thru holes, and then the non-conductive base 102 is fired according to well-known methods. Next, a conductive material is applied to the first surface 103 of non-conductive base 102 to form the conductive layer 106 and to the second surface 205 of non-conductive base to form a ground layer 240. In another embodiment of the invention, the exploded view in FIG. 3 shows conductive layer 106 further includes a second ground layer 302 on the first surface 103 of the non-conductive base 102. The second ground layer 302 can be sized to cover various portions of the first surface of the non-conductive base to enhance the grounding of the lid and the shielding wall. FIG. 3 illustrates one example of second ground layer 302 having three sections separated by the transmission lines such that the second ground layer 302 does not come into contact with the transmission lines 118 and 122. The second ground layer is made of a conductive material preferably having excellent electrical conductivity, examples of which are described above with respect to conductive layer 106, and with variations in the mixtures providing various levels of hermeticity, wire bondability, solderability, etchability and adhesion.

The conductive layer 106 and the first ground layer 240 can be applied to the non-conductive base 102 by thick-film deposition, for example, screen printing or combined screen printing and etching and etching techniques, and by thin-film techniques such as by sputtering, chemical and physical vapor deposition processes, and by a combination of thick-film and thin-film technology. Highly demanding applications, in the high frequency domain, for example, telecom and aerospace packaging applications, require high density circuitry that has line widths typically as large as about 1000 microns and line accuracy typically within about 1 micron. In another embodiment, the thick-film method of applying the conductive material is used in combination with photolithographic and etch techniques to define high resolution lines. The details regarding the process for producing high resolution lines can be found in the following publications which are hereby incorporated by reference herein: “Innovation in High Frequency Fabrication”, Zentrix Technologies, Inc., Brochure C000, May, 2001; ECP (Enhanced Circuit Processing) Process Flow Chart, Zentrix Technologies, Inc., Dec. 6, 2001; “Ceramic Build Up Design Guide”, Zentrix Technologies, Inc., Dec. 6, 2001.

This combination of thick-film and yields conductive patterns with substantially smooth, flat surface topology, well-defined edges, and near vertical walls, which are all key requirements for good impedance control and low insertion loss at high frequencies that reach 100 GHz and higher. The first conductive layer can have a conductive pattern with line width and line spacing that ranges from about 10 to about 1000 microns, more commonly from about 75 to about 750 microns, and most typically, from about 100 to 500 microns. The thick-film method also allows for integrating transmission lines, inductors, Lange couplers, laser trimmable thick-film resistors, capacitors and other passives such as filters onto the non-conductive base. The conductive material is applied to the second surface of non-conductive base so that the first ground layer has a thickness of up to about 100 microns, and preferably from about 5 to about 50 microns. The thickness of the first ground layer is a function of the impedance and other features of the integrated microwave package.

After the first conductive layer 106 is applied to the non-conductive base 102 an isolating layer 232 is applied to at least a portion of the transmission lines that extends under the shielding wall 104. Once the isolating layer is applied, the non-conductive base 102 is fired at temperatures that typically range from about 850° C. to about 1000° C. The isolating layer can be any material that isolates the transmission lines from ground, such as, for example, screen printed dielectric paste or “tape transfer” type dielectric tape. Tape transfer dielectric tape can be obtained from Heraeus Incorporated of Coshocken, Pa. under the tradename Heratape 710 or from Electro-Science Laboratories, Inc. of King of Prussia, Pa. The material for isolating layer 232 should be selected such that the requisite firing conditions will not cause the first conductive layer 106 to melt or flow during firing. The thickness of isolating layer 232 can be selected to achieve the dielectric properties necessary for the transmission lines based on the application. The dielectric constant of the tape transfer dielectric tape can be varied and typically ranges from about 4 to about 10. The tape transfer dielectric tape is typically available, and therefore applied, in a thickness that ranges from about 100 microns to 200 microns. After firing, the tape thickness shrinks in the z direction down to a thickness of about 50 to about 100 microns. Shrinkage in the x-y plane is typically less than about 1 percent, and preferably, less than about 0.5 percent.

The isolating layer 232 can be sized and applied to cover only the areas of the transmission lines that extend under the shielding wall, however, the dielectric layer can also be applied to a larger portion of the non-conductive base. For example, isolating layer 232 in FIG. 3 is sized to substantially match the dimensions and annular shape of the shielding wall 104. The isolating layer 232, which isolates the transmission lines from the shielding wall, can also allow the shielding wall 104 to connect to the ground plane 240. As illustrated in FIG. 3, isolating layer 232 has a plurality of openings or holes 304 filled with conductive material, such as, for example, the conductive material used in via 220 described above, including gold, silver, silver-palladium, platinum, and mixtures thereof, and are positioned to interconnect with a plurality of vias 306 which extend through non-conductive base 102 to the ground plane 240. Isolating layer 232 isolates transmission lines 118 and 122 from ground yet also facilitates electrical connection of the shielding wall 104 to the ground layer 240.

The process for making an integrated microwave package further includes attaching the shielding wall 104 to the non-conductive base 102. In one embodiment the process preferably includes attaching a metallization layer 234 and a first bonding layer 236 to the isolating layer 232 before attaching the shielding wall 104. The metallization layer 234 and the conductive bonding layer 236 improve the bond strength and hermeticity between the dielectric layer and the shielding wall. The metallization layer 234 can be applied by screen printing, for example, conductive material onto the isolating layer 232 and then firing the metallization layer 234 onto the isolating layer 236 and the non-conductive base 102. Next, the first bonding layer 236, which can be made of a metallic brazing or soldering material, is applied between the metallization layer 234 and the shielding wall 104. The shielding wall 104 is then brazed or soldered onto the metallization layer by applying heat. Materials selected for the metallization layer 234 and the conductive bonding layer 238 should have a melting temperature that is high enough to braze or solder but not so high that the conductive pattern on the non-conductive base will loose its integrity or flow during sintering or brazing. In another embodiment, rather than applying a metallization layer 234, the first bonding layer 236, can be made of a conductive epoxy or conductive adhesive, for example, and can be applied directly to isolating layer 232 on non-conductive base or shielding wall 104, or both. The non-conductive base and shielding wall are placed into contact until epoxy or adhesive is cured.

In an integrated microwave package having a first multilayer circuit structure 150 described above, layers of conductive material and dielectric material can be applied to the non-conductive base according to one of several processing alternatives to build the first multilayer circuit structure. The processing steps are determined in part by the type of dielectric material that is used to construct the first multilayer circuit structure.

In one embodiment of the invention, the first multilayer circuit structure is built up on at least a portion of the first surface of the non-conductive base 102 and the conductive layer 106 thereon by applying a dielectric paste. The dielectric paste is supplied by Heraeus Incorporated of Coshocken, Pa., EMCA of Montgomeryville, Pa., FERRO of Santa Barbara, Calif., the DuPont Company of Wilmington, Del. and Electro-Science Laboratories, Inc. of King of Prussia, Pa. and can be applied by methods well known by those skilled in the art, for example, by screen printing. The dielectric paste is applied to the first conductive layer 106 in a pattern that includes an opening or hole for at least one via. The dielectric paste disposed on the first conductive layer is then typically fired at temperatures that range from about 850° C. to about 1000° C., depending on the type of dielectric paste, to produce a first dielectric layer. After the dielectric paste is fired to produce a first dielectric layer, a conductive material is then applied to the first dielectric layer and to the opening created therein. The conductive material is then dried and fired preferably at a temperature that ranges from about 850° C. to about 1000° C. to produce at least one metallized via that extends through the first dielectric layer. Additional conductive material is then applied to the first dielectric layer in a conductive pattern, and the conductive material on the non-conductive base 102 is then dried and fired preferably at a temperature that ranges from about 850° C. to about 1000° C. to produce a second conductive layer disposed on the first dielectric layer. Suitable conductive materials include, for example, the same conductive materials used to produce conductive layer 106 disposed on the first surface of non-conductive base 102 described above. The above steps of applying dielectric material and conductive material can be repeated several times to produce a non-conductive base having multiple dielectric layers and conductive layers. The number of layers of the first multilayer circuit structure depends on desired functionality of the integrated microwave package of a given application.

In a preferred embodiment the process for constructing a first multilayer circuit structure is carried out using a tape transfer dielectric tape to produce the dielectric layers. Tape transfer dielectric tape can be obtained from Electro-Science Laboratories, Inc. of King of Prussia, Pa. and Heraeus Inc. of Conshohocken, Pa. as described with reference to a material that can be used for isolating layer 232 in FIG. 2 above. The processing steps include forming openings or holes in the tape transfer dielectric tape by laser drilling or punching, for example. The dielectric tape with at least one hole therein is positioned on the first conductive layer of the non-conductive base 102 so that via openings are in registration with a desired location of the first conductive layer 106. Once the dielectric tape is registered, pressure is applied to the tape transfer dielectric tape and then the tape transfer dielectric tape disposed on the non-conductive base is fired. Firing the dielectric tape bonds it to the non-conductive based and the first conductive layer to produce the first dielectric layer. Next, the conductive material is applied to the first dielectric layer to fill the hole or opening created therein. The conductive material is dried, preferably at a temperature that ranges from about 100° C. to about 150° C. for about 10-20 minutes, and fired, preferably at a temperature that ranges from about 850° C. to about 1000° C., to produce a metalized via. Conductive material is then applied to the first dielectric layer using a conventional or high resolution thick-film process, such as, for example, screen printing, described above with respect to the conductive layer 106 above. The conductive material is then dried, preferably at a temperature that ranges from about 100° C. to about 150° C. for about ten to twenty minutes, and fired, preferably at a temperature that ranges from about 850° C. to about 1000° C., to produce a second conductive layer. The above steps of applying dielectric material, in the form of tape transfer dielectric tape, and conductive material can be repeated several times to produce a multilayer circuit structure of the integrated microwave package. The number of layers of the first multilayer circuit structure depends on desired functionality of the integrated microwave package of a given application.

In another embodiment of the invention, a process for constructing a multilayer circuit structure on non-conductive base 102 may be achieved using low temperature co-fired ceramic tape (LTCC) that is sintered using the low temperature co-fired ceramic process. In the LTCC process, openings or holes are formed in individual sheets of LTCC tape. The openings are filled with conductive material to construct vias. The sheets of LTCC tape having staggered and stacked vias are interconnected by conductive layers formed during a screen printing process, for example, are stacked on each other and laminated. The laminated stack is then placed on the conductive layer 106 of the non-conductive base 102 and fired at about 800-900° C. LTCC tape is commercially available from several manufacturers including Heraeus Inc., Heralock™ 2000, for example, EMCA of Montgomeryville, Pa., FERRO of Santa Barbara, Calif., and the DuPont Company of Wilmington, Del. In another embodiment, a multilayer circuit structure made with LTCC tape using the LTC process is fired separately and then bonded on the non-conductive base 102 in a separate bonding step, using conventional brazing, solder, or conductive adhesive technology, for example, using the materials described above.

Several additional design features can be included in the integrated microwave package of the present invention to improve the electrical and thermal performance. The following embodiments discuss these features which can be used alone or in combination with an integrated RF, microwave or millimeter wave package having a grounded shielding wall, lid and transmission lines with minimal or no discontinuities.

In another embodiment of the invention, the non-conductive base of the integrated microwave package has a cavity for confining an integrated circuit mounted therein. Preferably, the integrated circuit is attached in the non-conductive base and recessed in the cavity so that it is substantially coplanar with the first conductive layer and transmission line disposed on the first surface of the non-conductive base. By substantially coplanar, it is meant that the signal received or generated by the integrated circuit are substantially in the same plane as signals received, generated, or sensed by the first conductive layer, the transmission line and the multilayer circuit structure. Co-planarity reduces the insertion loss associated with the package and is especially advantageous in high power and high frequency applications.

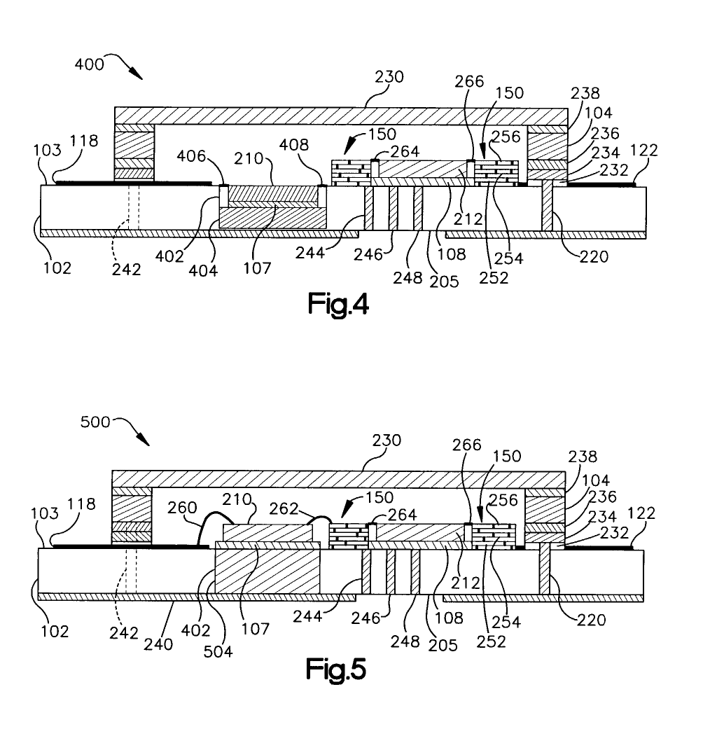

FIG. 4 shows a cross-sectional view of integrated microwave package 400 which is similar to the cross-sectional view of electronic package 100 in FIG. 2 except that pedestal 404 resides in a cavity 402 of non-conductive base 102. Pedestal 402 can be sized such that the integrated circuit 210 mounted thereon is substantially coplanar with the first conductive layer 106 of the first surface 103 of non-conductive base 102. The cavity 402 is shown extending through the non-conductive base 102 such that the pedestal 404 comes into contact with ground plane 240. In a preferred embodiment of the invention, the pedestal 404 is made of a metallic material having a thermal conductivity that is greater than the thermal conductivity of the non-conductive base 102 to improve heat conduction away from the integrated circuit 210, and in addition, has a coefficient of thermal expansion that approximately matches that of the semiconductor material used to make the integrated circuit.

The pedestal can be made in any shape and dimension, and the size of the pedestal depends on the size of the integrated circuit, the size of the non-conductive base, and functionality objectives of the package to be achieved. In FIG. 5 pedestal 504 extends the full length of cavity 402 through the non-conductive base 102. In this embodiment the integrated circuit 210 is disposed on the first surface 103 of non-conductive base 102 and is substantially coplanar with multilayer circuit structure 150.

Any of the known methods for electrically connecting the integrated circuit to a conductive pattern of a conductive layer and to a transmission line, according to the interconnection bonding technology described above, can be used. The integrated circuit 210 of FIG. 5 is shown, for example, to be electrically connected to transmission line 118 by wire bond 260, and is connected to multilayer circuit structure 150 by wire bond 262. However, ribbon bonds can be used as in FIG. 4, in which the integrated circuit 210 is electrically connected to multilayer circuit structure 150 by ribbon bond 408 and to transmission line 118 by ribbon bond 406. When the integrated circuit is coplanar or substantially coplanar with any components such as, for example, conductive pattern of a multilayer circuit structure, a conductive pattern disposed on the non-conductive base, and the transmission lines, ribbon bonding can also be used as an alternative to wire bonds. This allows for higher frequency connections by introducing lower inductance.

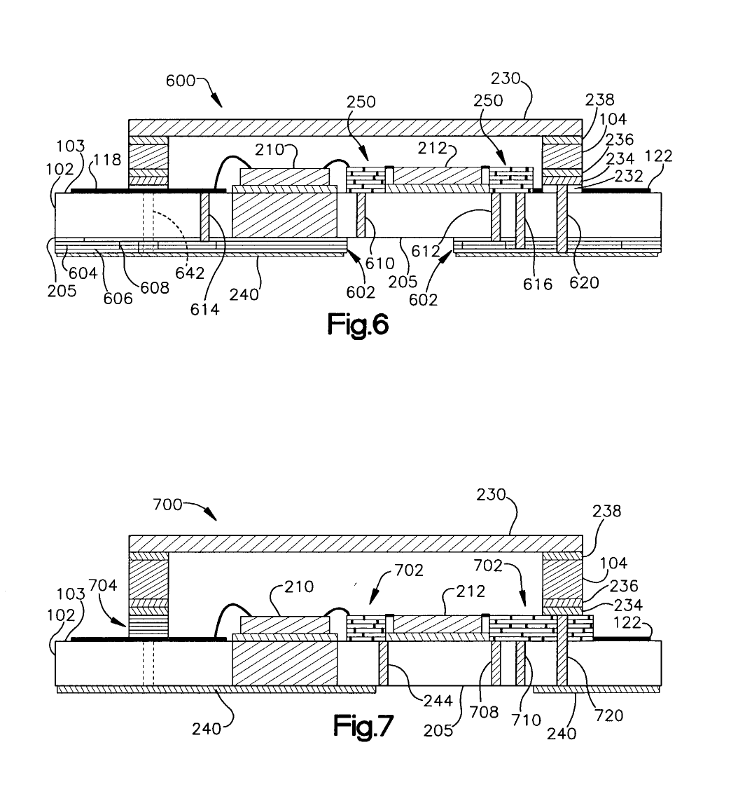

In another embodiment of the present invention, the integrated microwave package includes a second multilayer circuit structure as an integral portion of the second surface 205 of non-conductive base 102. FIG. 6 shows second multilayer circuit structure 602 made up a plurality of dielectric layers, for example, dielectric layer 604 and a plurality of conductive layers, for example, conductive layer 606 disposed therebetween. One or more via 608 connect the conductive layers 606 between the insulating layers 604. The multilayer circuit structure 602 extends along at least a portion of the second surface 205 of the non-conductive base 102. FIG. 6 illustrates one embodiment in which the second multilayer circuit structure is disposed between the second surface 205 of the non-conductive base and the first ground layer 240. The shielding wall 104 and conductive lid 230 are grounded through vias 620 and 642. In another embodiment (not shown) the first ground layer can be disposed between the second surface of the non-conductive base and the second multilayer circuit structure.

A myriad of grounding and interconnection combinations are possible. For example, RF and DC interconnections can be routed through via 612 and via 616 which extend from the multilayer circuit structure 150 on, through the non-conductive base, and to any conductive layer of multilayer circuit structure 602. Heat conducting vias, for example, via 610, can simply extend through the non-conductive base 102 for interconnection to external components.

The process for making an integrated microwave package having a second multilayer circuit structure is the same as the processes described for making the first multilayer circuit structure with reference to FIG. 3. Although not shown in FIG. 6, the integrated microwave package of the present invention can include both a first multilayer circuit structure and a second multilayer circuit structure.

FIG. 7 illustrates, according to another embodiment of the present invention, an integrated microwave package 700 wherein the first multilayer circuit structure 702 disposed on the first surface 103 of non-conductive base 102 extends underneath shielding wall 104. A multilayer circuit structure that extends under the shielding wall increases the utilized surface area of the electronic package for increased functionality. Via 720 extends through multilayer circuit structure 702 to ground layer 240 to electrically ground the shielding wall 104 and lid 230. In one embodiment the metallization layer 234 can be in direct contact with the top dielectric layer of the multilayer circuit structure and an isolating layer 232 shown in FIG. 2 is not necessary to isolate the transmission line 122 from the shielding wall 104.

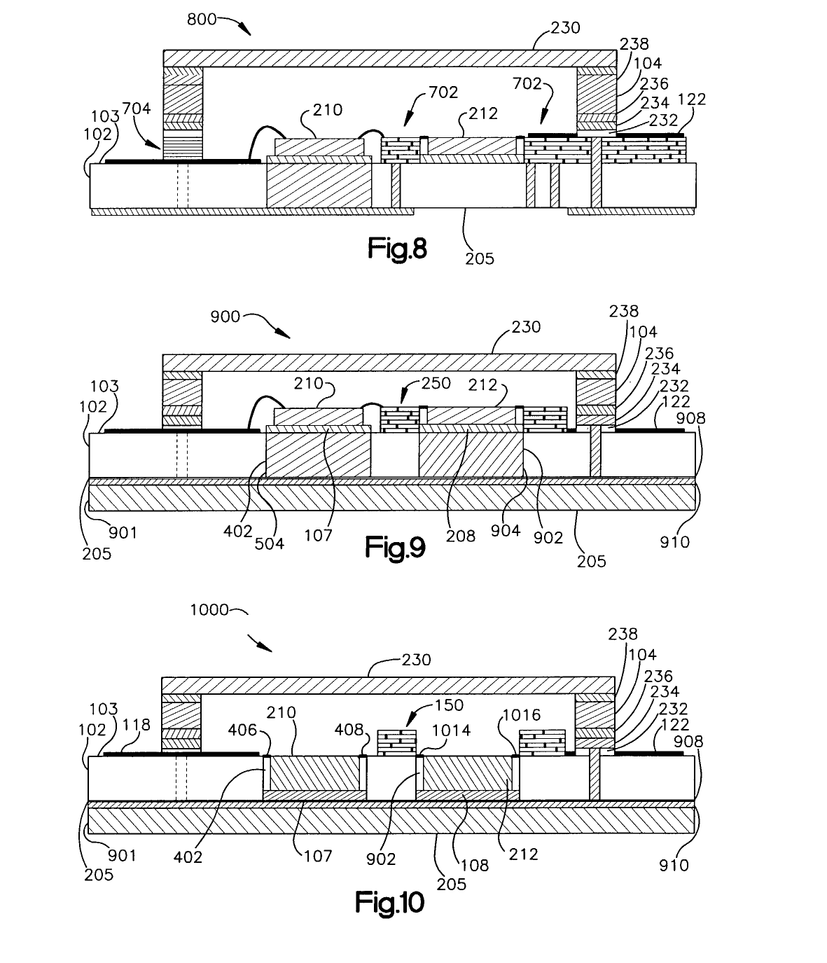

FIG. 8 is similar to FIG. 7 except that transmission line 822 is disposed on the top conductive layer of the multilayer circuit structure 702 which extends under the shielding wall 104. In this arrangement the transmission line 822 can be substantially coplanar with integrated circuit. Isolating layer 232 electrically isolates the transmission line 822 from the shielding wall 104. The isolating layer 232 can be dielectric thick film paste, tape transfer dielectric tape, LTCC ceramic tape, or any material that insulates the transmission line from the shielding wall and also maintains the transmission line impedance, as described above with respect to FIG. 2. Metallization layer 234 is adhered to layer 232 and bonding layer 236 is adhered to metallization layer 234, as discussed above with respect to FIG. 3, for attachment of shielding wall 104.

In another embodiment of the invention, FIG. 9 illustrates electronic package 900 having a metallic substrate 901 attached to the second surface 205 of the non-conductive base 102. The metallic substrate can be attached to the non-conductive base by applying a metallization layer 908 onto the non-conductive base and by applying the third bonding layer 910, such as a metallic solder or a brazing compound, to the metallization layer 908 or the metallic substrate 902 or both. A metallic solder or a brazing compound, such as, for example, gold-germanium, gold-tin, gold silicon, tin-lead, and copper-silver can be used, although other suitable compounds will be apparent to those skilled in the art. If a metallization layer is not applied, a conductive adhesive, for example, a conductive epoxy, that adheres the metallic substrate 901 to the non-conductive base 102 can be used.

The metallic substrate 901 can have a substantial thickness, for example, up to about 30 mils or greater to provide for enhanced heat transfer from the integrated circuit to the external environment. FIG. 9 shows that integrated circuits 210 and 212 are mounted on pedestals 504 and 904, respectively, which are bonded to the metallic base 901 for improved electrical and thermal conductivity a better thermal expansion match. In another embodiment, the pedestals 504 and 904 can be an integral feature of the metallic substrate 901. Materials suitable for metallic base 901 and pedestals 504 and 904 preferably include copper, silver, gold, aluminum, metallic alloys such as copper silver, beryllium copper, and beryllium nickel, and metal matrix composites and composites that have the appropriate material properties of high thermal conductivity and high electrical conductivity. Metal matrix composites such as, for example, copper/tungsten, copper beryllium/tungsten and copper/molybdenum, and other composites including copper/silicon carbide, beryllia/beryllium including E-MATERIALS™ such as E60 (60 vol. % beryllia and 40 vol. % beryllium), E40 (40 vol. % beryllia and 60 vol. % beryllium), and E20 (20 vol. % beryllia and 80 vol. % beryllium), aluminum/silicon carbide (preferably 55 to 75 vol. % silicon carbide), Silvar™, copper-aluminum nitride, copper graphite, copper diamond, copper-cubic boron nitride, and other metal matrix composites that exhibit an appropriate thermal conductivity and a thermal expansion are also appropriate. Other refractory metals suitable for forming metal matrix composites include chromium, niobium, tantalum, vanadium, and titanium.

In FIG. 10, according to another embodiment of the invention, electronic package 1000 has a metallic substrate 901 that extends along at least a portion of the bottom surface 205 of the non-conductive base 102. Non-conductive base 102 is illustrated with two cavities 402 and 902 with the integrated circuits 210 and 212 disposed therein. The integrated circuits can be bonded to the metallic substrate 901 by attaching to bonding pads 107 and 108.

In this configuration, electrical and heat dissipation can be greatly improved. The recessed integrated circuits 210 and 212 can be substantially coplanar with the RF plane and transmission lines 118 and 122 located on the first surface of the non-conductive base 102. This allows electrical connection between the integrated circuits and other electronic devices of the package by one of the many interconnecting bonding technologies discussed above. For example, integrated circuit 210 is electrically connected to the conductive pattern on the first surface of non-conductive base 102 by ribbon bonds 406 and 408.

In another embodiment of the invention the integrated microwave package further comprises an optical fiber which allow light to be transmitted through the integrated microwave package and which is connected to an active optical component disposed on the mounting area defined by the shielding wall and is intended for optoelectronic applications. The optical fiber accesses the interior of the package through a metallic hossel attached to the shielding wall or the lid, or through an opening on the base. When the hossel is used, this would provide for a hermetic package. When an opening is used to introduce the optical fiber, the package would be non-hermetic. The active optical component can include but are not limited to, for example, a laser transmitter diode, laser diode, PIN (positive-intrinsic-negative) photodiode, or APD (avalanche) photodiode. These devices produce or detect light. The integrated microwave package of this embodiment can be used in optoelectronic modules such as transmitters, receivers, modulators, switches, MUX-DEMUX, power amplifiers, and drivers, for example. In a preferred embodiment the optical fibers extend through the shielding wall and are hermetically sealed.

A microelectronic broad band package, according to the present invention, meets the requirements of the several applications of differing frequency pass bands as listed in Table I below, although there are other frequencies and applications in which this package could be used.

TABLE I
Wireless Frequency Applications

| Frequency | | Frequency Class | Applications |
|---|---|---|---|
| 2-40 | MHz | HF (High | AM Broadcast, Land |
| | | Frequency) | Mobile Radio, Paging |
| 55-88 | MHz | VHF (Very | VHF TV, Band 1 |
| | | High Frequency) | |
| 88-108 | MHz | VHF | FM Broadcast |
| 174-230 | MHz | VHF | VHF, Band III |
| 400-950 | MHz | VHF | Pulsed radar |
| 470-860 | MHz | VHF | UHF TV, Band IV + V, |
| | | | Paging |
| 824-849 | Mhz | Cellular | AMPS/Analog |
| 872-905 | Mhz | Cellular | ETAC/Analog |
| 900 | MHz | | ISM (Industrial, Scien- |
| | | | tific Medical Band) |
| 898-928 | MHz | Cellular | Spread Spectrum, Analog |
| | | | Cellular, PCS |
| 960 MHz-1.6 | GHz | GPS | Global Pos. System |
| 1.9 | GHz | | Broad Band PCS, UHF |
| | | | TV Relay |
| 2.4 | GHz | Microwave | Spread Spectrum PCS |
| 2.15-2.69 | GHz | Microwave | Wireless Cable TV |
| 2.4 | GHz | Microwave | ISM (Industrial, |
| | | | Scientific, Medical Band) |
| 2.5 | GHz | Microwave | MMDS (Microwave |
| | | | Multipoint Distribution |
| | | | System) |
| 5.4 | GHz | Microwave | LAN (Local Area |
| | | | Network) |
| 5.8 | GHz | Microwave, C-Band | ISM (Industrial, Scien- |
| | | | tific, Medical Band) |
| 6.0, 10.0, 11.0, | | Microwave | Microwave Radio |
| 12.0, 15.0, 18.0 | GHz | | |
| 18.0, 24.0 | GHz | Microwave | DEMS (Digital |
| | | | Electronic Messaging |
| | | | System) |
| 23.0, 26.0, 31.0, | | Millimeter | Millimeter Radio |
| 38.0, 50.0 | GHz | | |
| 24.0 | GHz | Millimeter | ISM (Industrial, Scien- |
| | | | tific, Medical Band) |
| 28.0, 31.0 | GHz | Millimeter | LMDS (Local Multipoint |
| | | | Distribution System) |
| 28.0 | GHz | Millimeter | LMCS (Local Multipoint |
| | | | Communication System) |
| 42.0 | GHz | Millimeter | MVDS (Multipoint |
| | | | Video Distribution |
| | | | System) |
| 60 | GHz | Millimeter | Automotive, Anti- |
| | | | collision (Japan Norm) |
| 76-77 | GHz | Millimeter | Automotive, Anti- |
| | | | collision front car radar |
| | | | (Europe Norm) |
| 92-95 | GHz | Millimeter | Defense Radar Systems |
| 95-100 | | Millimeter | Vehicle Anti-collision |
| | | | radar |

Typically, for applications listed in Table I the integrated microwave package must have low insertion loss, high return loss, and good shielding to result in lower radiated and dispersive noise. The insertion loss should be less than about 3 dB throughout the pass band for broadband applications, and less than about 0.5 dB for narrow band applications.

It will be understood that the specific embodiments of the invention shown and described here in are exemplary only. Numerous variations, changes, substitutions and equivalents will occur to those skilled in the art without departing from the spirit and scope of the present invention. Accordingly, it is intended that all subject matter described herein and shown in the accompanying drawings be regarded as illustrative only and not in a limiting sense. Various modifications are contemplated and can be made without departing from the spirit and scope of the invention as defined by the appended claims.

What is claimed is:

1. An integrated microwave package that comprises:
a non-conductive base having a first surface and a second surface opposite the first surface;
a first conductive layer disposed on the non-conductive base comprising a conductive pattern and a transmission line for transmitting radio frequency (RF) signals in and out of the microwave package;
a first ground layer disposed on the second surface of the non-conductive base;
a shielding wall electrically connected to the first ground layer and disposed on the first surface of the non-conductive base, defining a mounting area thereon;
wherein a portion of the transmission line is disposed on the non-conductive base and between the non-conductive base and the shielding wall;
an isolating layer is disposed between the transmission line and the shielding wall.

2. The integrated circuit structure of claim 1 further comprising:
a via that extends from the first surface of the non-conductive base to the second surface of the non-conductive base to electrically connect the shielding wall to the first ground layer.

3. The integrated microwave package of claim 1 wherein:
at least a portion of the conductive pattern of the first conductive layer has a line width and line spacing, each of which ranges from about 10 to about 1000 microns.

4. The integrated package of claim 3 wherein:
at least a portion of the conductive pattern is made of a thick-film conductive material comprising silver or gold.

5. The integrated package of claim 4 wherein the conductive pattern is of high resolution produced by a photolithography and etch process.

6. The integrated package of claim 1 wherein the integrated microwave package further comprising:
a multilayer circuit stricture disposed on at least a portion of the first surface of the non-conductive base comprising a plurality of conductive layers separated by a plurality of dielectric layers, the conductive layers are electrically connected by at least one metallized via.

7. The integrated microwave package of claim 1 further comprising:
a multilayer circuit structure disposed on at least a portion of the first surface of the non-conductive base comprising:
at least a portion of the first conductive layer disposed on the non-conductive base;
a first dielectric layer disposed on the first conductive layer;
a second conductive layer disposed on the first conductive layer; and
at least one metallized via that electrically connects the first conductive layer to the second conductive layer.

8. The integrated microwave package of claim 7 wherein:
the first and the second conductive layers each have a conductive pattern, the conductive pattern having a line width and line spacing each which ranges from about 10 to about 1000 microns.

9. The integrated microwave package of claim 8 wherein:
at least a portion of the conductive pattern of the first conductive layer and the second conductive layer are made from a of thick-film conductive material comprising silver or gold.

10. The integrated package of claim 9 wherein:
at least a portion of each conductive pattern is of high resolution produced by a photolithography and etch process.

11. The integrated microwave package of claim 10 further comprising:
a metallization layer and a first bonding layer for attaching the shielding wall to the non-conductive base wherein:
the metallization layer is disposed between the non-conductive base and the shielding wall and between the isolating layer and the shielding wall;
the first bonding layer is disposed between the metallization layer and the shielding wall;
the metallization layer comprises a material selected from the group consisting of gold, silver, copper, palladium, platinum, molybdenum, molymanganese, tungsten, silver-palladium, silver-palladium-platinum, molybdenum-tungsten, gold-silver-palladium, gold-silver-platinum, and mixtures thereof; and
the first bonding layer comprises a material selected from the group consisting of gold-tin, gold-germanium, gold-silicon, tin-lead, tin-lead-silver, copper-silver, gold-indium, and mixtures thereof.

12. The integrated microwave package of claim 11 further comprising:
a second ground layer disposed on the first surface of non-conductive base between the non-conductive base and the shielding wall.

13. The integrated microwave package of claim 10 further comprising:
a first bonding layer for attaching the shielding wall to the non-conductive base wherein:
the first bonding layer is disposed between the non-conductive base and the shielding wall, and between the isolating layer and the shielding wall; and
the first bonding layer is made of a conductive adhesive.

14. The integrated microwave package of claim 13 further comprising:
a second ground layer disposed on the first surface of non-conductive base between the non-conductive base and the shielding wall.

15. The integrated microwave package of claim 1 further comprising:
an integrated circuit mounted to the non-conductive base on the mounting area inside the shielding wall; and
wherein the integrated circuit is electrically connected to the conductive pattern and the transmission line.

16. The integrated microwave package of claim 15 further comprising:
a lid attached to the shielding wall and electrically connected to the first ground layer.

17. The integrated microwave package of claim 16 further comprising:
a second bonding layer disposed between the shielding wall and the lid.

18. The integrated microwave package of claim 17 wherein:
the second bonding layer is made of a material selected from the group consisting of: gold-tin, gold-germanium, gold-silicon, tin-lead, tin-lead-silver, copper-silver, gold-indium and mixtures thereof.

19. The integrated microwave package of claim 17 wherein:
the second bonding layer is made of a conductive adhesive.

20. The integrated microwave package of claim 17 wherein:
the integrated microwave package is hermetic.

21. The integrated microwave package of claim 6 further comprising:
an integrated circuit mounted on the first surface of the non-conductive base; and
wherein the integrated circuit is substantially coplanar with the multilayer circuit structure.

22. The integrated microwave package of claim 1:
wherein the non-conductive base has a cavity; and
the integrated microwave package further comprises:
an integrated circuit disposed in the cavity.

23. The integrated microwave package of claim 22 wherein the integrated circuit is substantially coplanar with the transmission line.

24. The integrated microwave package of claim 22 wherein:
the cavity extends from the first surface of the non-conductive base to the second surface of the non-conductive base; and
the integrated circuit is mounted on a pedestal that is disposed within the cavity and attached to the non-conductive base.

25. The integrated microwave package of claim 24 wherein the pedestal is made of a metallic material.

26. The integrated microwave package of claim 24 wherein the pedestal is made of a material that has a higher thermal conductivity than the non-conductive base

27. The integrated microwave package of claim 7 further comprising:
a second multilayer circuit structure disposed on the second surface of the non-conductive base.

28. The integrated microwave package of claim 27 wherein the second multilayer circuit structure is electrically connected the first multi-layer structure disposed on the first surface of the non-conductive base.

29. The integrated microwave package of claim 28 wherein:
the first ground layer is disposed between the second surface of the non-conductive base and the second multilayer circuit structure.

30. The integrated microwave package of claim 28 wherein:
the second multilayer circuit structure is disposed between the second surface of the non-conductive base and the first ground layer.

31. The integrated microwave package of claim 1 wherein:
a metallic substrate is disposed on at least a portion of the second surface of the non-conductive base.

32. The integrated microwave package of claim 31 wherein:
the non-conductive base has a cavity that extends from the first surface of the non-conductive base to the second surface of the non-conductive base; and
a portion of the metallic substrate protrudes into the cavity and has an integrated circuit mounted thereon, the integrated circuit being substantially coplanar with the signals transmitted by the transmission line.

33. The integrated microwave package of claim 31 further comprising:
a third bonding layer disposed between the second surface of the non-conductive base and the metallic substrate.

34. The integrated microwave package of claim 1 further comprising:
a metallization layer disposed between the non-conductive base and the shielding wall and between the isolating layer and the shielding wall;
a first bonding layer disposed between the metallization layer and the shielding wall;
the metallization layer comprises a material selected from the group consisting of gold, silver, copper, palladium, platinum, molybdenum, molymanganese, tungsten, silver-palladium, silver-palladium-platinum, molybdenum-tungsten, gold-silver-palladium, gold-silver-platinum, and mixtures thereof; and
the first bonding layer comprises a material selected from the group consisting of gold-tin, gold-germanium, gold-silicon, tin-lead, tin-lead-silver, copper-silver, gold-indium and mixtures thereof.

35. The integrated microwave package of claim 33 wherein:
the third bonding layer is made of a material selected from the group consisting of: a conductive adhesive, gold-tin, gold-germanium, gold-silicon, tin-lead, tin-lead-silver, copper-silver, gold-indium and mixtures thereof.

36. An integrated microwave package that comprises:
a non-conductive base having a first surface and a second surface opposite the first surface;
a first conductive layer disposed on the non-conductive base comprising a conductive pattern and a transmission line for transmitting radio frequency (RF) signals in and out of the microwave package;
a first ground layer disposed on the second surface of the non-conductive base;
a second ground layer disposed on the first surface of the non-conductive base;
a shielding wall electrically connected to the first ground layer and disposed on the first surface of the non-conductive base, defining a mounting area thereon;
wherein a portion of the transmission line is disposed on the non-conductive base and between the non-conductive base and the shielding wall;
an isolating layer is disposed between the transmission line and the shielding wall;
a multilayer circuit structure disposed on at least a portion of the first surface of the non-conductive base comprising:
at least a portion of the first conductive layer disposed on the non-conductive base;
a first dielectric layer disposed on the first conductive layer;
a second conductive layer disposed on the first conductive layer; and
at least one metallized via that electrically connects the first conductive layer to the second conductive layer;
an integrated circuit mounted to the non-conductive base and electrically connected to the conductive pattern and the transmission line; and
a lid attached to the shielding wall and electrically connected to the first ground layer.

37. An integrated microwave package intended for optoelectronic applications, the package comprises:
a non-conductive base having a first surface and a second surface opposite the first surface;
a first conductive layer disposed on the non-conductive base comprising a conductive pattern having a transmission line for transmitting radio frequency (RF) signals in and out of the microwave package;
a first ground layer disposed on the second surface of the non-conductive base;
a shielding wall electrically connected to the ground layer and disposed on the first surface of the non-conductive base, defining a mounting area thereon;
wherein a portion of the transmission line is disposed between the non-conductive base and the shielding wall;
an isolating layer is disposed between the transmission line and the shielding wall; and
an optical fiber that extends through the shielding wall.

38. The integrated optoelectronic microwave package of claim 37 further comprising:
an active optical component disposed on the mounting area of the non-conductive base and in optical communication with the optical fiber.

39. The process for making an integrated microwave package comprising the steps of:
forming an opening between a first surface and a second surface of a non-conductive base;
filling the opening with conductive material to create a metallized via through the non-conductive base;
drying the conductive material;
firing the metallized vias through the non-conductive base via;
forming a first conductive layer comprising a conductive pattern and a transmission line on the first surface of the non-conductive base;
forming a first ground layer on the second surface of the non-conductive base;
drying the first conductive layer and the first ground layer;
firing the first conductive layer and the first ground layer of the non-conductive base;
attaching an isolating layer to at least a portion of the transmission line disposed on the first surface of the non-conductive base; and
attaching a shielding wall to the first surface of the non-conductive base.

40. The process of claim 39 further comprising:
forming a second ground layer on first surface of non-conductive and firing the non-conductive base before attaching the shielding wall to the first surface of the non-conductive base.

41. The process of claim 39 further comprising:
applying a metallization layer to the non-conductive base or the isolating layer or both;
applying a first bonding layer to the metallization layer or the shielding wall or both;
placing the shielding wall into contact with the first surface of the non-conductive base;
wherein the metallization layer comprises a material selected from the group consisting of gold, gold-platinum, silver, silver-palladium, moly-mangnanese, nickel, copper, copper alloys, copper-silver, tin, copper-tin, silver-palladium, silver-palladium-platinum, molybdenum-tungsten, gold-silver-palladium, gold-silver-platinum and mixtures thereof; and
wherein the first bonding layer comprises a material selected from the group consisting of gold-tin, gold-germanium, gold-silicon, tin-lead, tin-lead-silver, copper-silver, gold-indium and mixtures thereof.

42. The process of claim 41 further comprising:
constructing a first multi-layer surface structure by:
applying a first dielectric layer on a pattern of the first conductive layer;
firing the non-conductive base with the first conductive pattern and the first dielectric layer thereon;
applying a second conductive layer onto the first dielectric layer; and
firing the non-conductive base with the second conductive layer thereon.

43. The process of claim 40 further comprising:
attaching an integrated circuit to the first surface of a non-conductive base.

44. The process of claim 43 further comprising electrically connecting the integrated circuit to the first conductive layer.

45. The process of claim 42 wherein the process further comprises:
forming a cavity in the non-conductive base;
placing the conductive pedestal into the cavity and attaching the pedestal to the cavity;
attaching the integrated circuit to the pedestal; and
positioning the pedestal so that the integrated circuit is coplanar with the signal transmitted through the first conductive layer disposed on the non-conductive base.

46. The process of claim 45 further comprising attaching a lid to the shielding wall.

47. The process of claim 45 wherein the process for forming the first conductive layer comprises:
applying a thick film conductive material onto the first surface of the non-conductive base;
firing the conductive material; and
applying a photolithography and etch process the first conductive layer to achieve high resolution conductive patterns.

48. The process of claim 47 further comprising:
constructing a second multi-layer circuit structure on the second surface of the non-conductive base.

49. The process of claim 48 further comprising:
attaching a metallic substrate to at least a portion of the second surface of the non-conductive base.

50. The process of claim 49 wherein:
the metallic substrate is attached to the second surface of the non-conductive base by applying a metallization layer to the second surface of the non-conductive base;
applying a third bonding layer to the metallic substrate or the metallization layer; and
wherein the third bonding layer is a metallic braze or metallic solder.

51. The process of claim 49 wherein:
the metallic substrate is attached to the second surface of the non-conductive base by using a conductive adhesive.
